(19) United States
(12) Patent Application Publication
(10) Pub. No.: US 2025/0299847 A1
(43) Pub. Date: Sep. 25, 2025

(54) LIQUID METAL-VITRIMER COMPOSITES

(71) Applicant: VIRGINIA TECH INTELLECTUAL PROPERTIES, INC., Blacksburg, VA (US)

(72) Inventors: Michael D. Bartlett, Blacksburg, VA (US); Josh Worch, Blacksburg, VA (US); Dong Hae Ho, Blacksburg, VA (US); Meng Jiang, Blacksburg, VA (US)

(21) Appl. No.: 19/082,634

(22) Filed: Mar. 18, 2025

Related U.S. Application Data
(60) Provisional application No. 63/567,198, filed on Mar. 19, 2024.
(60) Provisional application No. 63/749,870, filed on Jan. 27, 2025.

(51) Int. Cl. H01B 1/12; C01G 15/00; H05K 1/09

(52) U.S. Cl. CPC H01B 1/124; C01G 15/00; H05K 1/09; C01P 2006/40; H05K 2201/0329

(57) ABSTRACT

Embodiments of a liquid metal (LM)-vitrimer composite that is reclaimable, recyclable, flexible, and electrically conductive are described. An example conductive composite includes a vitrimer matrix. The conductive composite further includes an electrically conductive percolated network of liquid metal elements disposed in the vitrimer matrix. Another example conductive composite includes a vitrimer matrix and a liquid metal-vitrimer composite layer disposed in the vitrimer matrix. The liquid metal-vitrimer composite layer includes an electrically conductive percolated network of liquid metal elements. An example device includes a substrate and a conductive composite coupled to the substrate. The conductive composite includes a vitrimer matrix. The conductive composite further includes an electrically conductive percolated network of liquid metal elements disposed in the vitrimer matrix.

### CROSS REFERENCE TO RELATED APPLICATIONS

This application claims the benefit of and priority to U.S. Provisional Application Ser. No. 63/749,870, filed Jan. 27, 2025, titled “LIQUID METAL-VITRIMER CONDUCTIVE COMPOSITE FOR RECYCLABLE AND RESILIENT ELECTRONICS,” the entire contents of which are hereby incorporated herein by reference. This application also claims the benefit of and priority to U.S. Provisional Application Ser. No. 63/567,198, filed Mar. 19, 2024, titled “LIQUID METAL-VITRIMER COMPOSITES,” the entire contents of which are hereby incorporated herein by reference.

### BACKGROUND

Electronic devices are ubiquitous in modern society, yet their poor recycling rates contribute to substantial economic losses and worsening environmental impacts from electronic waste (E-waste) disposal. Some components of E-waste can be partially recovered and later repurposed into new electronics parts. However, many modern electronic devices are high-performance composites featuring non-recyclable thermosetting plastics as a base material, which complicates separation and recycling efforts of these devices. As such, efforts to address the recycling inefficiencies of E-waste materials have been aimed at improving the recyclability or processability of the polymeric components.

Organic semiconducting polymers and derivative multi-material designs provide some direction toward flexible conductive plastics designs. Other approaches blend insulating, thermosetting polymers (i.e., permanent covalent networks) with conductive fillers such as graphene, carbon nanotubes, or rigid metallic particles to create electrically conductive composites.

Attention has also turned toward replacing permanent covalent bonds in conventional thermosets with dynamic covalent bonds to yield a dynamic covalent polymer network or vitrimer. The resulting vitrimer material is mechanically strong and chemically resistant like thermosets, but reconfigurable and recyclable like thermoplastics. As such, there has been interest in replacing traditional epoxy composites with epoxy vitrimer composites. Solid conductive fillers and low-melting-point metal alloys commonly referred to as liquid metals (LM) have also been successfully incorporated into vitrimer matrices.

### SUMMARY

Described herein are embodiments of a liquid metal (LM)-vitrimer composite that is reclaimable, recyclable, flexible, and electrically conductive. The LM-vitrimer composite can be embodied as a vitrimer-based, covalent adaptable network composite with microdroplets of gallium-indium (Ga—In) liquid metal in some examples. The LM-vitrimer composite exhibits a relatively high glass transition temperature, good solvent resistance, and high electrical conductivity while also displaying mechanical qualities of rigid thermosets, shape memory, reconfigurability, and recyclability. The LM-vitrimer composite can be used to form or incorporate various electrical components and circuits into different electronic devices, thereby providing a pathway towards fully recyclable, mechanically robust, and reconfigurable electronics and advancing the field of green electronic materials.

Aspects and advantages of embodiments of the present disclosure will be set forth in part in the following description or can be learned from the description or through practice of the embodiments. Other aspects and advantages of embodiments of the present disclosure will become better understood with reference to the appended claims and the accompanying drawings, all of which are incorporated in and constitute a part of this specification. The drawings illustrate example embodiments of the present disclosure and, together with the description, serve to explain the related concepts of the present disclosure.

According to one example embodiment, a conductive composite includes a vitrimer matrix. The conductive composite further includes an electrically conductive percolated network of liquid metal elements disposed in the vitrimer matrix.

According to another example embodiment, a conductive composite includes a vitrimer matrix. The conductive composite further includes a liquid metal-vitrimer composite layer disposed in the vitrimer matrix. The liquid metal-vitrimer composite layer includes an electrically conductive percolated network of liquid metal elements.

According to another example embodiment, a device includes a substrate and a conductive composite coupled to the substrate. The conductive composite includes a vitrimer matrix. The conductive composite further includes an electrically conductive percolated network of liquid metal elements disposed in the vitrimer matrix.

### BRIEF DESCRIPTION OF THE DRAWINGS

Many aspects of the present disclosure can be better understood with reference to the following figures. The components in the figures are not necessarily to scale, with emphasis instead being placed upon clearly illustrating the concepts of the disclosure. Moreover, repeated use of reference characters or numerals in the figures is intended to represent the same or analogous features, elements, or operations across different figures. Repeated description of such repeated reference characters or numerals is omitted for brevity.

FIG. 1A illustrates a perspective view of an example liquid metal (LM)-vitrimer conductive composite according to various aspects and embodiments of the present disclosure.

FIG. 1B illustrates a top-down view of the conductive composite shown in FIG. 1A according to various aspects and embodiments of the present disclosure.

FIG. 1C illustrates the cross-sectional view of the conductive composite designated A-A in FIG. 1B according to various aspects and embodiments of the present disclosure.

FIG. 2A illustrates a top-down view of another example LM-vitrimer conductive composite according to various aspects and embodiments of the present disclosure.

FIG. 2B illustrates the cross-sectional view of the conductive composite designated B-B in FIG. 2A according to various aspects and embodiments of the present disclosure.

FIG. 3 illustrates an example electrical activation process according to various aspects and embodiments of the present disclosure.

FIG. 4A illustrates a top-down view of an example LM-vitrimer conductive composite device according to various aspects and embodiments of the present disclosure.

FIG. 4B illustrates the cross-sectional view of the LM-vitrimer conductive composite device designated C-C in FIG. 4A according to various aspects and embodiments of the present disclosure.

FIG. 5A illustrates a top-down view of another example LM-vitrimer conductive composite device according to various aspects and embodiments of the present disclosure.

FIG. 5B illustrates the cross-sectional view of the LM-vitrimer conductive composite device designated D-D in FIG. 5A according to various aspects and embodiments of the present disclosure.

FIG. 6A illustrates a top-down view of another example LM-vitrimer conductive composite device according to various aspects and embodiments of the present disclosure.

FIG. 6B illustrates the cross-sectional view of the LM-vitrimer conductive composite device designated E-E in FIG. 6A according to various aspects and embodiments of the present disclosure.

FIG. 7 illustrates a perspective view of another example LM-vitrimer conductive composite device according to various aspects and embodiments of the present disclosure.

### DETAILED DESCRIPTION

Electronic devices are ubiquitous in modern society, yet their poor recycling rates contribute to substantial economic losses and worsening environmental impacts from electronic waste (E-waste) disposal. Some components of E-waste, such as gold electrodes and other precious metals, can be partially recovered by chemical treatment processes involving strong acids and later repurposed into new electronics parts. However, many modern electronic devices are high-performance composites featuring non-recyclable thermosetting plastics, such as epoxy-laminated fiberglass sheets, as a base material. The multi-component nature of E-waste complicates separation and recycling efforts, especially due to the extreme durability and chemical resistance of thermosets. As such, efforts to address the recycling inefficiencies of E-waste materials have been aimed at improving the recyclability or processability of the polymeric components.

The rise of organic semiconducting polymers in the 1990's-2000's signaled a path to flexible conductive plastics. However, these materials have challenges related to ambient stability and are brittle primarily due to their low molecular weights and high degree of semi-crystallinity, although advances in multi-material design have mitigated some of these limitations to drive recent developments in the bio-electronic sector. Other approaches have instead blended insulating, thermosetting polymers (i.e., permanent covalent networks) with conductive fillers such as graphene, carbon nanotubes, or rigid metallic particles creating electrically conductive composites. Although percolation thresholds <1 wt % can be reached for graphene and carbon nanotubes in many composites, obtaining optimized (plateau) conductivity values often requires significantly greater filler content. While this approach produces materials with good mechanical strength and stiffness in the GPa-range, they are not recyclable due to their permanent network structure.

Attention has turned toward replacing the permanent covalent bonds in conventional thermosets with dynamic covalent bonds to yield a dynamic covalent polymer network or vitrimer. The resulting material can flow after application of a stimulus (e.g., heat) to activate bond exchange reactions and enable melt-processing or reshaping. This unique property makes vitrimers mechanically strong and chemically resistant like thermosets, but reconfigurable and recyclable like thermoplastics. In this space, there has been considerable interest to replace traditional epoxy composites due to their high volume usage in many industries, including electronics, with epoxy vitrimer composites. The most common synthetic approach for epoxy vitrimer composites is to install dynamic ester linkages within the epoxy network using anhydrides or carboxylic acids as hardening agents, which requires harsh reaction conditions for curing and the addition of an exogenous catalyst (i.e., additionally added) to render the subsequent material dynamic. Together, these factors necessitate intricate manufacturing approaches, especially when including functional filler components.

Solid conductive fillers have been successfully incorporated into vitrimer matrices, but the bulk electrical conductivity is typically well below that of the respective pristine filler component. On the other hand, using low-melting-point metal alloys, commonly referred to as liquid metals (LM), offer the prospect of creating high-performance composites for reconfigurable electronics due to its high electrical and thermal conductivity, regenerative characteristics, and resistance to mechanical fatigue. However, using LM as a filler in high-Tg vitrimer composites remains rare. The few examples of LMs in vitrimer matrices have displayed functional properties like thermal conductivity but achieving electrical conductivity was not demonstrated. LMs have primarily been added to low-Tg, elastomeric polymers or gels to afford soft, healable electronic materials with electrical conductivities several orders of magnitude greater than composites with carbon-based fillers. These types of soft LM composites have also been shown to be recyclable, when water soluble or thermoplastic elastomer matrices are used which leverage weaker physical crosslinks, in flexible or stretchable systems. However, recyclable electrically conductive LM composites with plastic-like qualities, such as high-Tg coupled with high stiffness and flexibility or ductility, remain rare yet they are essential in modem electronic devices. This presents an opportunity to robust and recyclable materials for the reduction of E-waste.

The present disclosure is directed to various embodiments of a LM-vitrimer composite that is reclaimable, recyclable, highly flexible, and electrically and thermally conductive to address the aforementioned problems. Embodiments herein include recyclable electronic devices having a vitrimer-based composite with microdroplets of gallium-indium (Ga—In) liquid metal (LM) in many cases. The LM-vitrimer composite embodiments exhibit a relatively high glass transition temperature (e.g., greater than 130° C.), good solvent resistance, high electrical conductivity, and recyclability. The electrically conductive, yet plastic-like LM-vitrimer composite embodiments display mechanical qualities of rigid thermosets, as well as recyclability through a dynamic covalent polymer network.

A vitrimer synthesis can be used in some examples to form the LM-vitrimer composite and it can proceed without the need for a catalyst or a high curing temperature which enables facile fabrication of the composite materials. The as-synthesized vitrimer in many examples exhibits a rapid relaxation time (e.g., 0.1 second) and a high tensile modulus (e.g., greater than 1 gigapascal (GPa)) as well as a shape memory effect and reconfigurability. The composite exhibits high electrical conductivity (e.g., >0.8×10⁵ S/m) with LM volume loading as low as 5 vol % in some examples and it can be relied upon to incorporate electrical components into flexible or stretchable substrates in many examples. This enables the fabrication of fully vitrimer-based circuit boards having electrical components such as sensors and indicator light-emitting diodes (LEDs) integrated therein with LM-vitrimer conductive wiring in some embodiments. The LM-vitrimer composite embodiments herein provide a pathway towards fully recyclable, mechanically robust, and reconfigurable electronics, thus advancing the field of green electronic materials.

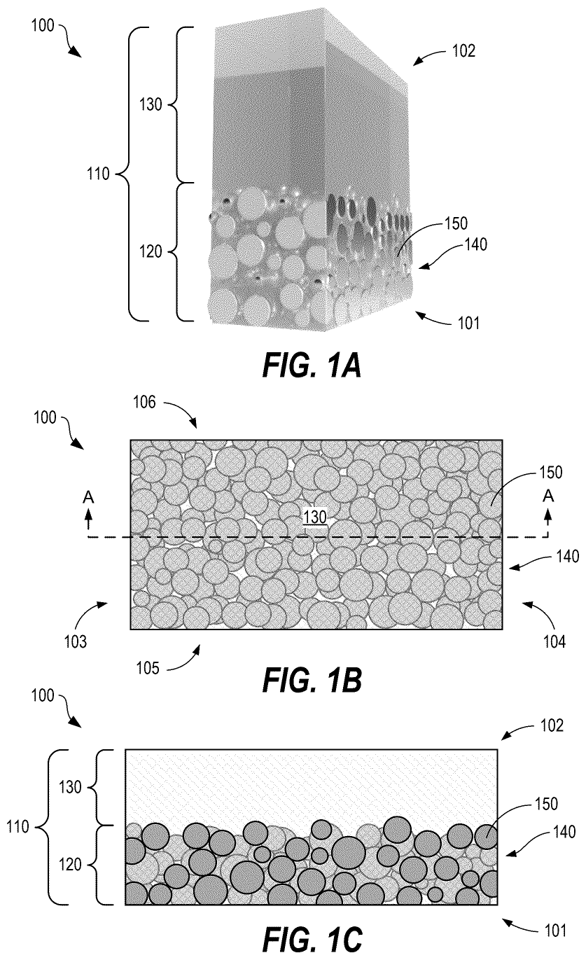

Turning now to the figures, FIG. 1A illustrates a perspective view of an example liquid metal (LM)-vitrimer conductive composite 100 (or “conductive composite 100”) according to various aspects and embodiments of the present disclosure. FIG. 1B illustrates a top-down view of the conductive composite 100 according to various aspects and embodiments of the present disclosure. FIG. 1C illustrates the cross-sectional view of the conductive composite 100 designated A-A in FIG. 1B according to various aspects and embodiments of the present disclosure.

The conductive composite 100 is an example embodiment of a reclaimable, recyclable, flexible (e.g., bendable, twistable), stretchable (e.g., elastic), and electrically and thermally conductive composite of the present disclosure. The conductive composite 100 is an example embodiment of the liquid metal (LM)-vitrimer conductive composite of the present disclosure. The conductive composite 100 can be embodied and implemented as a Janus or heterogeneous structure having an insulating region on one side and an electrically and thermally conductive region on an opposite side. The conductive region of the conductive composite 100 in various examples can be embodied as or include at least one of an electrode, an electrical trace, an electrical contact pad, an electrical interconnect, or another electrically conductive element. The conductive composite 100 is embodied as at least one of an electrically conductive electrode, trace, or interconnect in the example shown. The conductive composite 100 can be at least one of embedded in or formed on a surface of one or more of a rigid, flexible, stretchable, or elastic substrate. For instance, the conductive composite 100 can be at least one of embedded in or formed on a surface of one or more of a rigid, flexible, stretchable, or elastic substrate to couple one or more conductive elements (e.g., LEDs, sensors) to the substrate in some examples or to couple multiple conductive elements to one another in other examples. The conductive composite 100 can be at least one of embedded in or formed on a surface of a vitrimer substrate in some examples such as a substrate of pure or pristine vitrimer material or a vitrimer composite.

Referring among FIGS. 1A to 1C, the conductive composite 100 in the example shown includes a vitrimer matrix 110, a liquid metal (LM)-vitrimer composite layer 120, and a pristine or pure vitrimer layer 130. The LM-vitrimer composite layer 120 is disposed in the vitrimer matrix 110 at or along a first side 101 of the conductive composite 100, and the pure vitrimer layer 130 is formed in the vitrimer matrix 110 at or along a second side 102 of the conductive composite 100. The first side 101 and the second side 102 of the conductive composite 100 are opposite one another in this example.

The vitrimer matrix 110 can be embodied as or include a pure or pristine vitrimer matrix including pure or pristine vitrimer material in many examples. The vitrimer matrix 110 can be embodied as or include a single, pristine, pure, or homogeneous vitrimer material or another material having dynamic covalent bonding ability that can yield a dynamic covalent polymer network in many examples. The vitrimer matrix 110 in the example shown is embodied as a single, pristine, pure, or homogeneous vitrimer material with the LM-vitrimer composite layer 120 disposed within such vitrimer material and the pure vitrimer layer 130 formed adjacent to the LM-vitrimer composite layer 120. As referenced herein, a “pristine” or “pure” vitrimer material or “matrix” can refer to one having only a single type of vitrimer material with all other materials being omitted.

The LM-vitrimer composite layer 120 includes an electrically and thermally conductive percolated network 140 (or “CPN 140”). The CPN 140 is at least partly disposed or encased in or otherwise integrated into a portion of the vitrimer matrix 110 that is located along and adjacent to the first side 101 of the conductive composite 100 in the example shown. For instance, the CPN 140 is at least partly disposed or encased in or otherwise integrated into a region of pure or pristine vitrimer material in the vitrimer matrix 110 that is located along and adjacent to the first side 101 of the conductive composite 100.

The pure vitrimer layer 130 can be embodied as or include a single, pristine, pure, or homogeneous vitrimer material or another material having dynamic covalent bonding ability that can yield a dynamic covalent polymer network in many examples. The vitrimer material used to form the pure vitrimer layer 130 in the example shown is the same vitrimer material that is used to form the aforementioned region of pure or pristine vitrimer material at least partly encasing the CPN 140 in the LM-vitrimer composite layer 120. In other examples, the vitrimer material used to form the pure vitrimer layer 130 can be different vitrimer material compared to the vitrimer material used to form such a region of pure or pristine vitrimer material in the LM-vitrimer composite layer 120.

The CPN 140 in the example shown is embodied as and includes a plurality of electrically and thermally conductive liquid metal (LM) elements 150 that are coupled to one another to collectively form the CPN 140 in the LM-vitrimer composite layer 120 of the vitrimer matrix 110. Only a single LM element 150 is denoted in each of FIGS. 1A, 1B, and 1C for clarity. The LM elements 150 are coupled to one another to collectively form the CPN 140 as a single and approximately uniform and continuous structure in the example shown. For instance, the structure of the CPN 140 extends throughout and occupies most of the LM-vitrimer composite layer 120 to the outer surfaces of the vitrimer matrix 110 and to an outer surface of the CPN 140 that interfaces with the pure vitrimer layer 130 inside the vitrimer matrix 110.

The LM elements 150 are coupled to one another to collectively form one or more electrically and thermally conductive pathways in and through the CPN 140 and the vitrimer matrix 110. For example, the electrically and thermally conductive pathway or pathways can extend through the CPN 140 in the LM-vitrimer composite layer 120 from a first end 103 (e.g., distal end) of the conductive composite 100 to a second end 104 (e.g., distal end) of the conductive composite 100 (FIG. 1B). In another example, the electrically and thermally conductive pathway or pathways can extend through the CPN 140 in the LM-vitrimer composite layer 120 from a third end 105 (e.g., distal end) of the conductive composite 100 to a fourth end 106 (e.g., distal end) of the conductive composite 100 (FIG. 1B). In still another example, the electrically and thermally conductive pathway or pathways can extend through the CPN 140 in the LM-vitrimer composite layer 120 in various lateral and vertical directions between the ends 103, 104, 106c, 106 of the conductive composite 100 and between the first side 101 of the conductive composite 100 and an outer surface of the CPN 140 that interfaces with the pure vitrimer layer 130 inside the vitrimer matrix 110.

The conductive pathway or pathways described herein can facilitate continuous electrical and thermal conductivity along and adjacent to the first side 101 of the conductive composite 100 between the ends 103, 104, 105, 106 of the conductive composite 100 and between the first side 101 of the conductive composite 100 and an outer surface of the CPN 140 that interfaces with the pure vitrimer layer 130 inside the vitrimer matrix 110. Individual ones and subsets of the LM elements 150 shown in FIGS. 1A to 1C that are positioned at or near an edge of at least one of the CPN 140 or the conductive composite 100 are coupled (e.g., electrically, mechanically, thermally) to one another and at least partly form an outer surface of at least one of the CPN 140 or the conductive composite 100.

The CPN 140 is embodied as a reclaimable, recyclable, continuous, flexible, stretchable, and electrically and thermally conductive percolated metal structure formed in the vitrimer matrix 110 as a collection of the LM elements 150 coupled to one another in the example shown. Each of the LM elements 150 is embodied as a reclaimable, recyclable, flexible, stretchable, and electrically and thermally conductive metal element. When the conductive composite 100 is embedded in or deposited on a surface of a flexible or stretchable substrate to form an electronic device, the CPN 140 of coupled LM elements 150 formed in the vitrimer matrix 110 of the conductive composite 100 allows for the entire resulting electronic device to have at least one of reclaimable, recyclable, flexible, or stretchable properties.

The conductive composite 100 can be formed into a variety of geometries and dimensions. The conductive composite 100 is formed into an approximately rectangular shape in the example shown, although it may be formed to another shape in some cases.

The vitrimer matrix 110 can include various volume fractions (ϕ) or percentages (vol %) of the LM elements 150 relative to all pure or pristine vitrimer material in the vitrimer matrix 110 (e.g., relative to all pure or pristine vitrimer material in both the LM-vitrimer composite layer 120 and the pure vitrimer layer 130 combined). The vitrimer matrix 110 can include volume fractions ϕ of the LM elements 150 ranging from approximately 5% to 95% in different examples. The vitrimer matrix 110 can include a volume fraction ϕ of the LM elements 150 that is less than 5% in some cases and more than 95% in other cases. The vitrimer matrix 110 in one example can include a volume fraction ϕ of the LM elements 150 that is approximately 20% relative to all pure or pristine vitrimer material in both the LM-vitrimer composite layer 120 and the pure vitrimer layer 130.

The conductive composite 100 in the example shown includes a single LM-vitrimer composite layer 120 and a single CPN 140 formed in the vitrimer matrix 110. In other examples, the conductive composite 100 can be embodied as or include a multilayer conductive composite having multiple LM-vitrimer composite layers 120 or CPNs 140 formed in the vitrimer matrix 110. For instance, the conductive composite 100 in some cases can be embodied as or include pure vitrimer layers 130 formed between multiple LM-vitrimer composite layers 120 or CPNs 140 in the vitrimer matrix 110. Such LM-vitrimer composite layers 120 or CPNs 140 can have the same volume fraction ϕ of the LM elements 150 relative to all pure or pristine vitrimer material in the vitrimer matrix 110 in some cases or different volume fractions ϕ in other cases.

In other examples, the LM elements 150 can individually include an alloy of gallium and indium. The LM elements 150 can be individually embodied as a micro-scale liquid metal element (e.g., a micro-sized liquid metal particle or droplet). The LM elements 150 can be individually formed to various diameters across the micro-scale or micrometer (μm) range in many examples. The LM elements 150 can each be formed to a diameter of approximately 80 μm in one example, and other diameters greater or less than 80 μm can be relied upon in some cases. The LM elements 150 can be individually embodied as a eutectic gallium-indium liquid metal element. The LM elements 150 can be individually embodied as a eutectic gallium-indium liquid metal element having a gallium to indium mass ratio of 3:1. The LM elements 150 in the example shown are individually embodied as a micro-scale eutectic gallium-indium liquid metal element (e.g., a micro-sized liquid metal particle or droplet) having a gallium to indium mass ratio of 3:1 (e.g., 75 wt % gallium, 25 wt % indium).

The conductive composite 100 can be applied as a manually stenciled ink in some examples. The conductive composite 100 can be applied as an automatically deposited direct ink write printing ink in other examples. The conductive composite 100 can also be embedded in, deposited on, or embedded in and deposited on a surface of a substrate in other cases. The conductive composite 100 is curable at an ambient temperature ranging between 20° C. and 100° C., and other temperatures can be relied upon in some cases. The conductive composite 100 is curable at an ambient temperature of approximately 40° C. for 3 hours in one example, and other temperatures or durations can be relied upon in some cases.

The electrical resistance of the CPN 140 and the conductive composite 100 can range in different examples depending on the volume fraction ϕ of the LM elements 150 in the vitrimer matrix 110. The CPN 140 and the conductive composite 100 can have an electrical conductivity of at least 2.0×10⁵ S/m in one example. The CPN 140 and the conductive composite 100 can have an electrical conductivity of less than or approximately 2.0×10⁵ S/m in another example.

The electrical and thermal conductivity of the CPN 140 and the conductive composite 100 can be activated by performing one or more mechanical activation processes on the conductive composite 100 in many examples. For instance, the electrical and thermal conductivity can be activated by performing one or more of sintering, embossing, cold working, mechanical agitation, mechanical abrasion, mechanical etching, or mechanical scratching on one or more surfaces (e.g., the sides 101, 102, the ends 103, 104, 105, 106) of the conductive composite 100. Such a mechanical activation process can be performed to align and couple (e.g., electrically and thermally) one or more subsets of the LM elements 150 or all of the LM elements 150 in some cases, thereby forming one or more conductive pathways of the CPN 140 in the vitrimer matrix 110.

The conductive composite 100 is an example embodiment of a LM-vitrimer microdroplet composite that displays mechanical qualities of rigid thermosets yet recyclability through a dynamic covalent polymer network. The electrically conductive, plastic-like composite 100 shows excellent thermomechanical properties in examples using a mild curing process approximately at or above 40° C. via ring-opening polymerization of an ester-based epoxy resin and amine hardener with LM droplets added in situ during polymerization.

During a curing procedure that can be performed in producing the conductive composite 100 in one example, the LM droplets 150 (e.g., eutectic Ga—In (EGaIn) LM microdroplets) can settle to the first side 101 of the conductive composite 100 to form the LM-vitrimer composite layer 120 as a region of conductive functionality and form the pure vitrimer layer 130 as a region of insulating functionality. The conductive composite 100 can exhibit relatively high Tg (e.g., >130° C.), high elastic modulus (e.g., approximately 1 gigapascal (GPa)), good solvent resistance, high electrical conductivity (e.g., >2.0×10⁵ S/m), reconfigurability or shape memory, and recyclability in many examples.

Unlike previous LM incorporated composites which have focused on permanent covalent networks or physically crosslinked networks for soft devices, the vitrimer matrix 110 of the conductive composite 100 provides a unique combination of electrical conductivity, robust thermomechanical performance, high modulus, and recyclability without loss of electrical conductivity under high loads or deformation in many examples. The conductive composite 100 establishes a pathway toward fully recyclable, mechanically robust, and reconfigurable electronics, thus advancing the field of green electronic materials.

It is important to understand the thermomechanical and rheological behavior of the vitrimer matrix 110 before incorporating the LM elements 150 for subsequent composite fabrication. Pure ester-based epoxy vitrimer can be synthesized in one example by reacting diglycidylphthalate (DP) with 1,3-bis-(aminomethyl)cyclohexane (AH) via ring-opening polymerization of epoxy. Although the epoxide is in molar excess relative to the primary amine (—NH₂) in this example, each primary amine unit (—NH₂) in AH can theoretically react twice with an epoxide moiety of DP. However, the steric hindrance around a secondary amine is much higher than that around a primary amine, reducing its ability to attack a second epoxide in this example. Nevertheless, the secondary amines that do react with epoxide units in this example can serve as dynamic covalent crosslinks to form a transient polymer network. The secondary (e.g., after one addition) and/or tertiary (e.g., after two additions) amines in the formed network in this example can also serve as built-in internal catalysts for subsequent transesterification reactions during remolding, advantageously avoiding the use of an exogenous catalyst.

To assess the relative degree of crosslinking in the conductive composite 100, gel content and swelling ratio were experimentally determined in one example. A 10 millimeter (mm) pre-weighed disk sample was swollen in a corresponding solvent for 7 days (d) in this example. The sample was then removed, and residual solvent on the surface was wiped with a Kimwipe prior to weighing in this example. Besides methanol that may be able to swell and partially dissolve the polymer well, a high gel fraction was observed in most solvents which indicates the as-synthesized polymer was sufficiently crosslinked in the conductive composite 100 in this example. This was further confirmed with mechanical testing of the conductive composite 100 under tension in this example, where the ultimate strength ranged between 60 and 80 megapascals (MPa), further supporting the above noted high crosslinking density.

With the support of Fourier-transform infrared (FTIR) spectroscopy, the absence of a transmittance (a.u.) peak at a 908 cm⁻¹ wavenumber in this example indicated that unreacted epoxide was undetectable in the conductive composite 100. Thermogravimetric analysis (TGA) revealed that the as-synthesized conductive composite 100 in this example had a T_{d,5%} at 298° C. which is above the required working temperature in most applications. Differential scanning calorimetry (DSC) of the conductive composite 100 sample also showed a (T_{g}) range between 125° C. to 150° C. in this example suggesting a highly cross-linked network.

Stress relaxation experiments were performed on a rheometer at different temperatures in one example to analyze the bulk flow behavior from dynamic bond exchange by applying 1% deformation to the conductive composite 100 material and monitoring the modulus over time. Usually, a conventional polymer network or thermoset, such as epoxy, used in electronic materials cannot relax the stress under any conditions due to permanent covalent bonding. With a dynamic covalent bond incorporated into the conductive composite 100 as described in examples herein, the stress can be relaxed over time when the bond is activated under certain triggers, such as elevated temperature.

Transesterification reactions typically need to be activated at high temperatures so the conductive composite 100 material was assessed between 170° C. and 200° C. in one example to determine an optimal temperature with a reasonable relaxation time for subsequent remolding of the vitrimer system. Arrhenius equation was used in this example to understand the temperature dependence of the transesterification reaction rate and determine the activation energy of the transesterification reaction in a bulk sample by plotting ln(t) against 1/T. The calculated activation energy (Eₐ) in this example was 43 kilocalories per mole (kcal/mol) which is comparable to previous literature values for epoxy vitrimers. With results from stress relaxation experiments, remolding tests were conducted in one example at 170° C. under 1.5 metric tons for 30 minutes up to 4 cycles. The remolded samples of the conductive composite 100 in this example showed good mechanical integrity. Due to the dynamic nature of ester bonds within the conductive composite 100 (e.g., within the vitrimer matrix 110), the conductive composite 100 can undergo healing, remolding, and chemical recycling.

The LM elements 150 were embodied as EGaIn liquid metal microdroplets in one example to achieve high electrical conductivity and flexibility in the conductive composite 100. The alloy EGaIn (e.g., 75 wt % gallium, 25 wt % indium) was selected in this example for its low toxicity and high electrical conductivity while retaining a sub-ambient melting temperature. Unlike fixed conductive paths in solid fillers, liquid conductive networks such as those of the CPN 140 in the LM-vitrimer composite layer 120 of the conductive composite 100 can be reconfigured when deformed in many examples, thereby offering stable electrical responses.

Incorporation of the LM elements 150 into a vitrimer polymer matrix such as the vitrimer matrix 110 can be accomplished in many examples by performing a shear mixing procedure. First, a designated volume fraction (ϕ_{LM}) of the LM elements 150 can be mixed with a viscous epoxy resin using a planetary mixer. During the mixing procedure, the shear stress inside the epoxy monomer can break the bulk LM into microdroplets (e.g., with diameters of approximately 80 micrometers (μm)). A diamine hardener can be incorporated into a reaction mixture and then the mixture can be poured into a polydimethyl siloxane (PDMS) mold followed by mild curing in a convection oven (e.g., at 40° C., 3 hours (h)) in this example.

During the curing procedure in this example, sedimentation of the LM microdroplet elements 150 occurs due to the density of LM. Sedimentation of the LM elements 150 results in a heterogeneous structure with the CPN 140 formed in the LM-vitrimer composite layer 120 such that the first side 101 of the conductive composite 100 is electrically conductive and the pure vitrimer layer 130 in the second side 102 of the conductive composite 100 is insulating. The localized concentration of the LM microdroplet elements 150 within a specified volume in one example is advantageous because it substantially reduces the distance between droplets, consequently effectively lowering the percolation threshold.

Theoretically, inclusion volume fractions (ϕ) of the LM elements 150 in excess of 25% are required for a 50% probability in forming a percolated network. However, due to the localized nature of the LM droplet elements 150, electrical conductivity can be achieved with a minimal LM volume fraction (ϕ_{LM}) as low as 5% in some examples. Because of intrinsic formation of a non-LM-containing layer in the vitrimer matrix 110, the pure vitrimer layer 130 naturally forms as an electrically insulating layer during fabrication of the conductive composite 100 in various examples. By increasing ϕ_{LM} in some examples, the thickness of the LM-vitrimer composite layer 120 increases. As ϕ_{LM} increases from 5% to 30%, the LM-vitrimer composite layer 120 accounts for a greater fraction of the total film thickness, increasing gradually from 10% to 55% in many examples. This allows for the conductive composite 100 to be fabricated with film architectures that resemble printed circuit board structures in some examples, with electrically conductive layers (e.g., the LM-vitrimer composite layer 120) and insulating layers (e.g., the pure vitrimer layer 130) inherently formed during the manufacturing process.

The LM elements 150 inside the solid polymer vitrimer matrix 110 impact the modulus and ductility of the vitrimer matrix 110 and the conductive composite 100 materials. The mechanical properties of various example LM-vitrimer composites such as were evaluated in different examples under tension using a universal testing machine. A pristine vitrimer such as the pure vitrimer layer 130 showed a modulus of approximately 1.8 GPa in one example, while the addition of the LM elements 150 decreased the modulus at all ϕ_{LM}. The modulus decreased for a ϕ_{LM} of 5% and then remained relatively constant around 1 GPa to ϕ_{LM} of 30% in one example, where the modulus reached a minimum value of 0.6 GPa. This decrease can be attributed to the liquid nature of the LM elements 150 and the sedimentation process. As ϕ_{LM} increased in many examples, the total thickness fraction of the LM-vitrimer composite layer 120 subsequently increased at a rate faster than the volume loading. This suggests that the LM-vitrimer composite layer 120 is not completely dense in some examples but instead forms as a foam-like structure within the rigid vitrimer that would be expected to soften the composite. The tensile strain at break of some example conductive composites 100 increases up to 2.4 times at ϕ_{LM} of 5%. With a further increase in ϕ_{LM} up to 30% in one example a gradual decrease in the tensile strain at break was observed, although these values remain above an epoxy-vitrimer sample.

The electrical properties of the conductive composite 100 were also investigated in different examples. The conductive composite 100 was first activated in one example using an embossing method similar to previous studies. Since the conductive composite 100 is rigid at room temperature, it was first softened with gentle heating in this example before embossing was performed at a designated location. A custom-made four probe measurement was then used in this example to measure the conductivity of the conductive composite 100 (e.g., the CPN 140). The conductive composite 100 (e.g., the CPN 140) became electrically conductive at small loadings of the LM elements 150 in many examples, where the ϕ_{LM}=5% composite displayed an electrical conductivity of 0.07×10⁶ S/m. This is notable, considering LM microdroplet-based composites with a uniform inclusion distributions typically require 20-50% ϕ_{LM} to become conductive. A further increase of ϕ_{LM} increases the conductivity in many examples. At 30% ϕ_{LM} in one example, the electrical conductivity increases to 0.2×10⁶ S/m.

Together these data from various examples above show that the conductive composite 100 can serve as a rigid plastic with high electrical conductivity. In one example, a volume fraction ϕ of approximately 20% ϕ_{LM} of the LM elements 150 in the conductive composite 100 (e.g., in the vitrimer matrix 110) was found to exhibit a desirable combination of mechanical and electrical attributes.

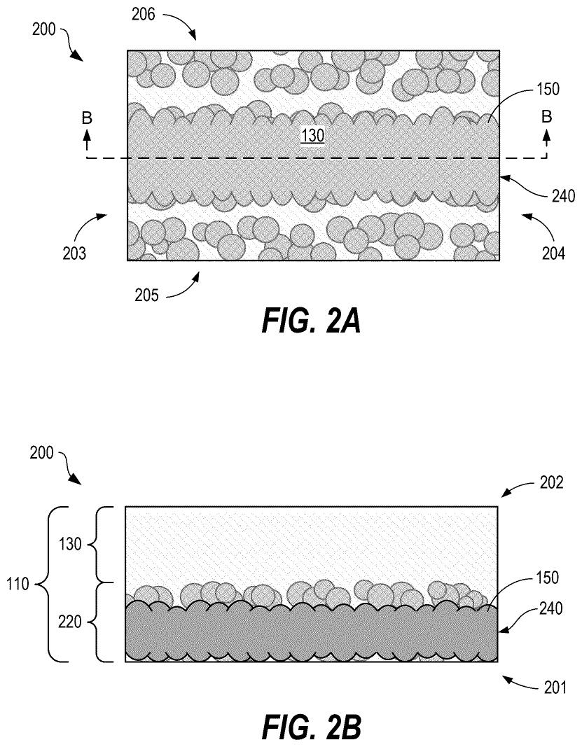

FIG. 2A illustrates a top-down view of another example liquid metal (LM)-vitrimer conductive composite 200 (or “conductive composite 200”) according to various aspects and embodiments of the present disclosure. FIG. 2B illustrates the cross-sectional view of the conductive composite 200 designated B-B in FIG. 2A according to various aspects and embodiments of the present disclosure.

The conductive composite 200 is an example alternative embodiment of the conductive composite 100 described herein with reference to FIGS. 1A to 1C. The conductive composite 200 can include or more of the same or similar materials, components, structure, attributes, and functional ability as that of the conductive composite 100.

The conductive composite 200 is another example embodiment of a reclaimable, recyclable, flexible (e.g., bendable, twistable), stretchable (e.g., elastic), and electrically and thermally conductive composite of the present disclosure. The conductive composite 200 is another example embodiment of the liquid metal (LM)-vitrimer conductive composite of the present disclosure. The conductive composite 200 can be embodied and implemented as a Janus or heterogeneous structure having an insulating region on one side and an electrically and thermally conductive region on an opposite side. The conductive region of the conductive composite 200 in various examples can be embodied as or include at least one of an electrode, an electrical trace, an electrical contact pad, an electrical interconnect, or another electrically conductive element. The conductive composite 200 is embodied as at least one of an electrically conductive electrode, trace, or interconnect in the example shown. The conductive composite 200 can be at least one of embedded in or formed on a surface of one or more of a rigid, flexible, stretchable, or elastic substrate. For instance, the conductive composite 200 can be at least one of embedded in or formed on a surface of one or more of a rigid, flexible, stretchable, or elastic substrate to couple one or more conductive elements (e.g., LEDs, sensors) to the substrate in some examples or to couple multiple conductive elements to one another in other examples. The conductive composite 200 can be at least one of embedded in or formed on a surface of a vitrimer substrate in some examples such as a substrate of pure or pristine vitrimer material or a vitrimer composite.

Referring among FIGS. 2A to 2C, the conductive composite 200 in the example shown includes the vitrimer matrix 110, a liquid metal (LM)-vitrimer composite layer 220, and the pure vitrimer layer 130. The LM-vitrimer composite layer 220 is disposed in the vitrimer matrix 110 at or along a first side 201 of the conductive composite 200, and the pure vitrimer layer 130 is formed in the vitrimer matrix 110 at or along a second side 202 of the conductive composite 200. The first side 201 and the second side 202 of the conductive composite 200 are opposite one another in this example.

The LM-vitrimer composite layer 220 includes an electrically and thermally conductive percolated network 240 (or “CPN 240”). The CPN 240 is at least partly disposed or encased in or otherwise integrated into a portion of the vitrimer matrix 110 that is located along and adjacent to the first side 201 of the conductive composite 200 in the example shown. For instance, the CPN 240 is at least partly disposed or encased in or otherwise integrated into a region of pure or pristine vitrimer material in the vitrimer matrix 110 that is located along and adjacent to the first side 201 of the conductive composite 200.

The vitrimer material used to form the pure vitrimer layer 130 in the example shown is the same vitrimer material that is used to form the aforementioned region of pure or pristine vitrimer material at least partly encasing the CPN 240 in the LM-vitrimer composite layer 220. In other examples, the vitrimer material used to form the pure vitrimer layer 130 can be different vitrimer material compared to the vitrimer material used to form such a region of pure or pristine vitrimer material in the LM-vitrimer composite layer 220.

The CPN 240 in the example shown is embodied as and includes a sintered subset of the electrically and thermally conductive LM elements 150 that are sintered or otherwise coupled to one another to collectively form the CPN 240 in the LM-vitrimer composite layer 220 of the vitrimer matrix 110. Only a single LM element 150 is denoted in each of FIGS. 2A, 2B, and 2C for clarity. The sintered subset of LM elements 150 are sintered or otherwise coupled to one another to collectively form the CPN 240 as a discrete, single, and approximately uniform and continuous structure in the example shown. For instance, the structure of the CPN 240 extends through and occupies a portion of the LM-vitrimer composite layer 220 and an outer surface of the CPN 240 interfaces with the pure vitrimer layer 130 inside the vitrimer matrix 110. In some cases, the structure of the CPN 240 is physically isolated and electrically insulated from other LM elements 150 in the LM-vitrimer composite layer 220 that are omitted from the CPN 240. For instance, a subset of the LM elements 150 that can be sintered or otherwise coupled to one another to form the CPN 240 can be physically isolated and electrically insulated from (e.g., not coupled to) other LM elements 150 that can be in the LM-vitrimer composite layer 220. For example, regions of pure or pristine vitrimer material in the LM-vitrimer composite layer 220 can physically isolate and electrically insulate the CPN 240 and the subset of LM elements 150 included therein from the LM elements 150 omitted from the CPN 240.

The LM elements 150 are sintered or otherwise coupled to one another in this example to collectively form one or more electrically and thermally conductive pathways in and through the CPN 240 and the vitrimer matrix 110. For example, the electrically and thermally conductive pathway or pathways can extend through the CPN 240 in the LM-vitrimer composite layer 220 from a first end 203 (e.g., distal end) of the conductive composite 200 to a second end 204 (e.g., distal end) of the conductive composite 200 (e.g., FIG. 2B). In another example, the electrically and thermally conductive pathway or pathways can extend through the CPN 240 in the LM-vitrimer composite layer 220 from a third end 205 (e.g., distal end) of the conductive composite 200 to a fourth end 206 (e.g., distal end) of the conductive composite 200.

In still other examples, the electrically and thermally conductive pathway or pathways can extend through the CPN 240 in the LM-vitrimer composite layer 220 in various lateral and vertical directions between the ends 203, 204 or the ends 206c, 206 of the conductive composite 200 and between the first side 201 of the conductive composite 200 and an outer surface of the CPN 240 that interfaces with the pure vitrimer layer 130 inside the vitrimer matrix 110. The conductive pathway or pathways can facilitate continuous electrical and thermal conductivity along and adjacent to the first side 201 of the conductive composite 200 between the ends 203, 204 or the ends 205, 206 of the conductive composite 200 and between the first side 201 of the conductive composite 200 and an outer surface of the CPN 240 that interfaces with the pure vitrimer layer 130 inside the vitrimer matrix 110. Individual ones and subsets of the LM elements 150 shown in FIGS. 2A to 2C that are positioned at or near an edge of at least one of the CPN 240 or the conductive composite 200 are sintered or otherwise coupled (e.g., electrically, mechanically, thermally) to one another in this example and at least partly form an outer surface of at least one of the CPN 240 or the conductive composite 200.

The CPN 240 is embodied as a reclaimable, recyclable, continuous, flexible, ductile, elastic, and electrically and thermally conductive percolated metal structure formed in the vitrimer matrix 110 as a sintered subset of the LM elements 150 coupled to one another in the example shown. Each of the LM elements 150 is embodied as a reclaimable, recyclable, flexible, stretchable, and electrically and thermally conductive metal element. When the conductive composite 200 is embedded in or deposited on a surface of a flexible or stretchable substrate to form an electronic device, the CPN 240 of a sintered or otherwise coupled subset of the LM elements 150 formed in the vitrimer matrix 110 of the conductive composite 200 allows for the entire resulting electronic device to have at least one of reclaimable, recyclable, flexible, or stretchable properties.

The conductive composite 200 can be formed to a variety of geometries and dimensions. The conductive composite 200 is formed to an approximately rectangular shape in the example shown, although it may be formed to another shape in some cases.

The vitrimer matrix 110 can include various volume fractions ϕ or percentages (vol %) of the LM elements 150 relative to all pure or pristine vitrimer material in the vitrimer matrix 110 (e.g., relative to all pure or pristine vitrimer material in both the LM-vitrimer composite layer 220 and the pure vitrimer layer 130 combined). The vitrimer matrix 110 can include volume fractions ϕ of the LM elements 150 ranging from approximately 5% to 95% in different examples. The vitrimer matrix 110 can include a volume fraction ϕ of the LM elements 150 that is less than 5% in some cases and more than 95% in other cases. The vitrimer matrix 110 in one example can include a volume fraction ϕ of the LM elements 150 that is approximately 20% relative to all pure or pristine vitrimer material in both the LM-vitrimer composite layer 220 and the pure vitrimer layer 130.

The LM elements 150 can individually include an alloy of gallium and indium. The LM elements 150 can be individually embodied as a micro-scale liquid metal element (e.g., a micro-sized liquid metal particle or droplet). The LM elements 150 can be individually formed to various diameters across the micro-scale or micrometer (μm) range in many examples. The LM elements 150 can each be formed to a diameter of approximately 80 μm in one example, and other diameters greater or less than 80 μm can be relied upon in some cases. The LM elements 150 can be individually embodied as a eutectic gallium-indium liquid metal element. The LM elements 150 can be individually embodied as a eutectic gallium-indium liquid metal element having a gallium to indium mass ratio of 3:1. The LM elements 150 in the example shown are individually embodied as a micro-scale eutectic gallium-indium liquid metal element (e.g., a micro-sized liquid metal particle or droplet) having a gallium to indium mass ratio of 3:1 (e.g., 75 wt % gallium, 25 wt % indium).

The conductive composite 200 can be applied as a manually stenciled ink in some examples. The conductive composite 200 can be applied as an automatically deposited direct ink write printing ink in other examples. The conductive composite 200 can also be embedded in, deposited on, or embedded in and deposited on a surface of a substrate in other cases. The conductive composite 100 is curable at an ambient temperature ranging between 20° C. and 100° C., and other temperatures can be relied upon in some cases. The conductive composite 200 is curable at an ambient temperature of approximately 40° C. for 3 hours in one example, and other temperatures or durations can be relied upon in some cases.

The electrical resistance of the CPN 240 and the conductive composite 200 can range in different examples depending on the volume fraction ϕ of the LM elements 150 in the vitrimer matrix 110. The CPN 240 and the conductive composite 200 can have an electrical conductivity of at least 2.0×10⁵ S/m in one example. The CPN 240 and the conductive composite 200 can have an electrical conductivity of less than or approximately 2.0×10⁵ S/m in another example.

The CPN 240 can be formed and the electrical and thermal conductivity of the conductive composite 200 can be activated in many examples by performing one or more mechanical activation processes on the conductive composite 100 described herein with reference to FIGS. 1A to 1C. For instance, the CPN 240 can be formed in the LM-vitrimer composite layer 220 of the conductive composite 200 by performing at least one of sintering, embossing, cold working, mechanical agitation, mechanical abrasion, mechanical etching, or mechanical scratching on one or more surfaces (e.g., the sides 101, 102, the ends 103, 104, 105, 106) of the conductive composite 100. Such a mechanical activation process can be performed to align and couple (e.g., electrically and thermally) one or more subsets of the LM elements 150 in the LM-vitrimer composite layer 220 of the vitrimer matrix 110, thereby simultaneously forming the CPN 240 and one or more conductive pathways of the CPN 240 in the vitrimer matrix 110.

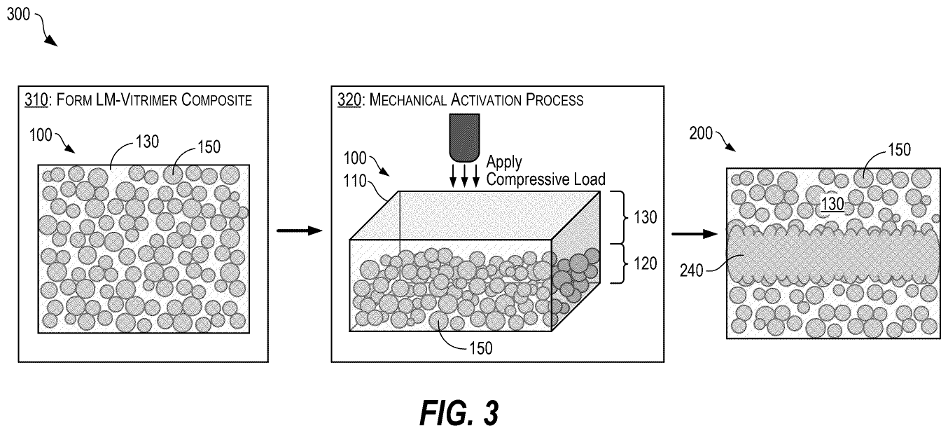

FIG. 3 illustrates an example electrical activation process 300 according to various aspects and embodiments of the present disclosure. The electrical activation process 300 can be implemented in many examples to fabricate the conductive composite 200 described herein with reference to FIGS. 2A to 2C. For instance, the electrical activation process 300 can be implemented to form the CPN 240 in the LM-vitrimer composite layer 220 of the conductive composite 200 and simultaneously activate the electrical and thermal conductivity of the conductive composite 200.

At 310, the electrical activation process 300 includes forming an LM-vitrimer composite. For instance, the electrical activation process 300 at 310 can include forming the conductive composite 100. For example, the electrical activation process 300 at 310 can include forming the conductive composite 100 with a certain volume fraction ϕ of the LM elements 150 that is the same as, similar to, or different from that illustrated in FIGS. 1A, 1B, and 1C.

At 320, the electrical activation process 300 includes performing a mechanical activation process on the LM-vitrimer composite formed at 310. For instance, the electrical activation process 300 at 320 can include performing at least one of sintering, embossing, cold working, mechanical agitation, mechanical abrasion, mechanical etching, or mechanical scratching on one or more surfaces (e.g., the sides 101, 102, the ends 104a, 104, 105, 106) of the conductive composite 100. In the example shown, the electrical activation process 300 at 320 includes embossing or otherwise applying a compressive load on the second side 102 of the conductive composite 100. Implementation of such embossing or other compressive load application at 320 can align and couple (e.g., electrically and thermally) one or more subsets of the LM elements 150 along or adjacent to the first side 101 of the conductive composite 100 in some cases. Such alignment and coupling of the LM elements 150 can simultaneously cause the formation of the CPN 240 in the vitrimer matrix 110 to yield the conductive composite 200 and the electrical and thermal activation of the conductive composite 200.

The mechanical activation process at 320 can be performed with the addition of heat in some examples or without added heat in other examples. For instance, the mechanical activation process at 320 can be a sintering process in some cases.

Each of the conductive composites 100, 200 possess qualities that are intrinsic to both thermoplastic and thermoset materials. One of the key advantages is their superior mechanical strength and rigidity owing to their highly crosslinked networks. To demonstrate this, different electronic circuits and devices can be fabricated using at least one of the conductive composites 100, 200 in several examples described herein.

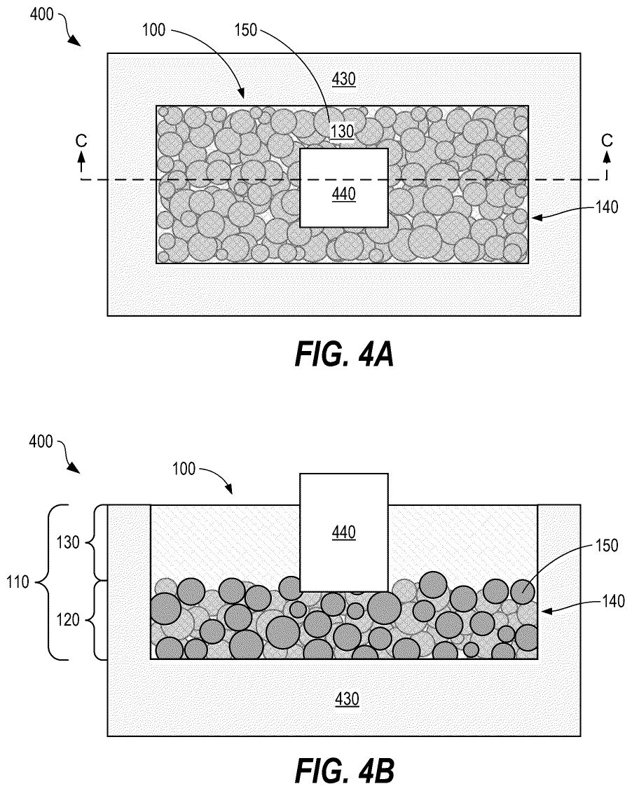

FIG. 4A illustrates a top-down view of an example liquid metal (LM)-vitrimer conductive composite device 400 (or “conductive composite device 400”) according to various aspects and embodiments of the present disclosure. FIG. 4B illustrates the cross-sectional view of the conductive composite device 400 designated C-C in FIG. 4A according to various aspects and embodiments of the present disclosure. The conductive composite device 400 is an example embodiment of a reclaimable, recyclable, flexible (e.g., bendable, twistable), stretchable (e.g., elastic), and electrically and thermally conductive composite device of the present disclosure.

Referring among FIGS. 4A and 4B, the conductive composite device 400 includes a substrate 430, a conductive element 440, and the conductive composite 100 coupled (e.g., electrically, mechanically, thermally) to the substrate 430 and the conductive element 440. For instance, at least a portion of each of the first side 101 of the conductive composite 100, the LM-vitrimer composite layer 120, the pure vitrimer layer 130, and the CPN 140 is coupled to the substrate 430, and at least another portion of each of the LM-vitrimer composite layer 120, the pure vitrimer layer 130, and the CPN 140 is coupled to the conductive element 440. The conductive composite 100 is embodied as at least one of an electrically conductive electrode, trace, or interconnect in the example shown. The conductive composite 100 can be at least one of embedded in or formed on a surface of the substrate 430. The conductive composite 100 is at least partly embedded in the substrate 430 in the example shown. The conductive composite 100 at least partly couples the conductive element 440 to the substrate 430 in this example. The conductive composite 100 can couple the conductive element 440 to one or more other conductive elements in another example such as one or more other conductive elements embedded in or formed on a surface of the substrate 430.

The substrate 430 can be embodied as at least one of a rigid, flexible, stretchable, or elastic substrate in many examples. The substrate 430 can be embodied as a silicon substrate in one example. The substrate 430 can be embodied as a crystalline silicon substrate in another example. The substrate 430 can be embodied as a silicon-on-insulator (SOI) substrate in yet another example. The substrate 430 is embodied as a vitrimer substrate in the example shown, although the substrate 430 can be embodied as another type of substrate in some cases. The substrate 430 can be embodied as a substrate formed from a pure or pristine vitrimer material in some examples or a vitrimer composite in other examples. The substrate 430 in the example shown is embodied as a substrate formed from a single, pristine, pure, or homogeneous vitrimer material or another material having dynamic covalent bonding ability that can yield a dynamic covalent polymer network. The vitrimer material used to form the substrate 430 in the example shown can be the same vitrimer material that is used to form the vitrimer matrix 110 of the conductive composite 100. In other examples, the vitrimer material used to form the substrate 430 can be different vitrimer material compared to the vitrimer material used to form the vitrimer matrix 110 of the conductive composite 100.

The conductive element 440 can be embodied as various types of conductive elements in different examples. For instance, the conductive element 440 can be embodied as at least one of an electrode, a light emitting diode (LED), a Hall effect sensor, a passive component, a resistor, a capacitor, an inductor, a sensor, a transformer, an integrated circuit (IC), or another conductive element.

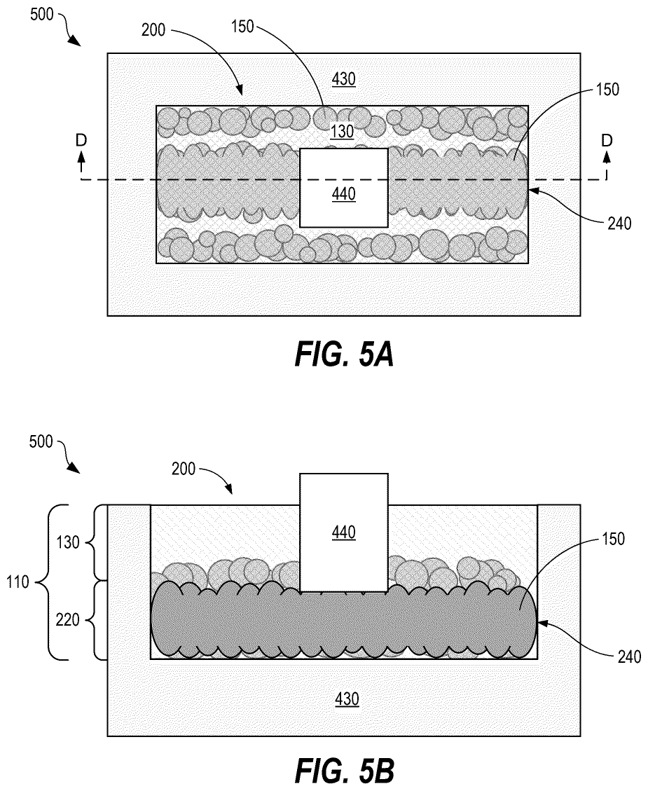

FIG. 5A illustrates a top-down view of another example liquid metal (LM)-vitrimer conductive composite device 500 (or “conductive composite device 500”) according to various aspects and embodiments of the present disclosure. FIG. 5B illustrates the cross-sectional view of the conductive composite device 500 designated D-D in FIG. 5A according to various aspects and embodiments of the present disclosure. The conductive composite device 500 is another example embodiment of a reclaimable, recyclable, flexible (e.g., bendable, twistable), stretchable (e.g., elastic), and electrically and thermally conductive composite device of the present disclosure.

The conductive composite device 500 is an example alternative embodiment of the conductive composite device 400 described herein with reference to FIGS. 4A and 4B. The conductive composite device 500 can include or more of the same or similar materials, components, structure, attributes, and functional ability as that of the conductive composite device 400.

Referring among FIGS. 5A and 5B, the conductive composite device 500 includes the substrate 430, the conductive element 440, and the conductive composite 200 coupled (e.g., electrically, mechanically, thermally) to the substrate 430 and the conductive element 440. For instance, at least a portion of each of the first side 201 of the conductive composite 200, the LM-vitrimer composite layer 220, the pure vitrimer layer 130, and the CPN 240 is coupled to the substrate 430, and at least another portion of each of the LM-vitrimer composite layer 220, the pure vitrimer layer 130, and the CPN 240 is coupled to the conductive element 440. The conductive composite 200 is embodied as at least one of an electrically conductive electrode, trace, or interconnect in the example shown. The conductive composite 200 can be at least one of embedded in or formed on a surface of the substrate 430. The conductive composite 200 is at least partly embedded in the substrate 430 in the example shown. The conductive composite 200 at least partly couples the conductive element 440 to the substrate 430 in this example. The conductive composite 200 can couple the conductive element 440 to one or more other conductive elements in another example such as one or more other conductive elements embedded in or formed on a surface of the substrate 430.

The substrate 430 can be embodied as at least one of a rigid substrate, a flexible substrate, a stretchable substrate, an elastic substrate, a silicon substrate, a crystalline silicon substrate, a silicon-on-insulator (SOI) substrate, a vitrimer substrate, or another substrate in various examples. The substrate 430 is embodied as a vitrimer substrate in the example shown, although the substrate 430 can be embodied as another type of substrate in some cases. The substrate 430 can be embodied as a substrate formed from a pure or pristine vitrimer material in some examples or a vitrimer composite in other examples. The substrate 430 in the example shown is embodied as a substrate formed from a single, pristine, pure, or homogeneous vitrimer material or another material having dynamic covalent bonding ability that can yield a dynamic covalent polymer network. The vitrimer material used to form the substrate 430 in the example shown can be the same vitrimer material that is used to form the vitrimer matrix 110 of the conductive composite 200. In other examples, the vitrimer material used to form the substrate 430 can be different vitrimer material compared to the vitrimer material used to form the vitrimer matrix 110 of the conductive composite 200.

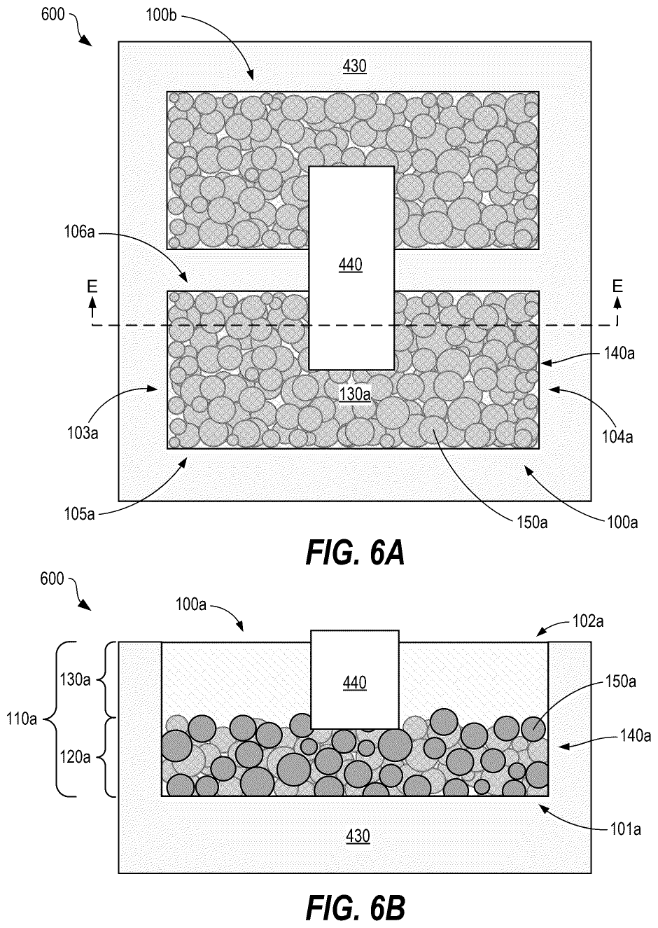

FIG. 6A illustrates a top-down view of another example liquid metal (LM)-vitrimer conductive composite device 600 (or “conductive composite device 600”) according to various aspects and embodiments of the present disclosure. FIG. 6B illustrates the cross-sectional view of the conductive composite device 600 designated E-E in FIG. 6A according to various aspects and embodiments of the present disclosure. The conductive composite device 600 is another example embodiment of a reclaimable, recyclable, flexible (e.g., bendable, twistable), stretchable (e.g., elastic), and electrically and thermally conductive composite device of the present disclosure.

The conductive composite device 600 is an example alternative embodiment of the conductive composite device 400 described herein with reference to FIGS. 4A and 4B. The conductive composite device 600 can include or more of the same or similar materials, components, structure, attributes, and functional ability as that of the conductive composite device 400.

Referring among FIGS. 6A and 6B, the conductive composite device 600 includes the substrate 430, the conductive element 440, and two of the conductive composites 100 coupled (e.g., electrically, mechanically, thermally) to the substrate 430 and the conductive element 440. In the example shown, the conductive composite device 600 includes two conductive composites 100a, 100b that are each coupled to the substrate 430 and the conductive element 440.

Each of the conductive composites 100a, 100b is an example alternative embodiment of the conductive composite 100 described herein with reference to FIGS. 1A to 1C. The conductive composites 100a, 100b can each include or more of the same or similar materials, components, structure, attributes, and functional ability as that of the conductive composite 100. For instance, the conductive composite 100a in the example shown includes a first side 101a, a second side 102a, a first end 103a, a second end 104a, a third end 105a, a fourth end 106a, a vitrimer matrix 110a, a liquid metal (LM)-vitrimer composite layer 120a, a pure vitrimer layer 130a, a conductive percolated network (CPN) 140a, and a plurality of LM elements 150a coupled to one another in the LM-vitrimer composite layer 120a to form the CPN 140a. The conductive composite 100b can include the same, similar, or different materials, components, structure, attributes, and functional ability compared to the conductive composite 100a. In the example shown, the conductive composite 100b includes the same or similar materials, components, structure, attributes, and functional ability as that of the conductive composite 100a.

Each of the conductive composites 100a, 100b is embodied as at least one of an electrically conductive electrode, trace, or interconnect in the example shown. Each of the conductive composites 100a, 100b can be at least one of embedded in or formed on a surface of the substrate 430. Each of the conductive composites 100a, 100b is at least partly embedded in the substrate 430 in the example shown. Each of the conductive composites 100a, 100b at least partly couples the conductive element 440 to the substrate 430 in this example. Each of the conductive composites 100a, 100b can couple the conductive element 440 to one or more other conductive elements in another example such as one or more other conductive elements embedded in or formed on a surface of the substrate 430.

The substrate 430 can be embodied as at least one of a rigid substrate, a flexible substrate, a stretchable substrate, an elastic substrate, a silicon substrate, a crystalline silicon substrate, a silicon-on-insulator (SOI) substrate, a vitrimer substrate, or another substrate in various examples. The substrate 430 is embodied as a vitrimer substrate in the example shown, although the substrate 430 can be embodied as another type of substrate in some cases. The substrate 430 can be embodied as a substrate formed from a pure or pristine vitrimer material in some examples or a vitrimer composite in other examples. The substrate 430 in the example shown is embodied as a substrate formed from a single, pristine, pure, or homogeneous vitrimer material or another material having dynamic covalent bonding ability that can yield a dynamic covalent polymer network. The vitrimer material used to form the substrate 430 in the example shown can be the same vitrimer material that is used to form each of the conductive composites 100a, 100b. In other examples, the vitrimer material used to form the substrate 430 can be different vitrimer material compared to the vitrimer material used to form one or both of the conductive composites 100a, 100b.

To fabricate the conductive composite device 600 in one example, a bar-shaped LM-vitrimer conductive composite (e.g., with ϕ_{LM}=20%) can be prepared to form a distinct anode and cathode for the conductive element 440. The LM-vitrimer conductive composites 100a, 100b can be positioned inside a polydimethylsiloxane (PDMS) mold and uncured vitrimer can then be poured into the PDMS mold. The sample can then be cured and subsequently extracted from the PDMS mold. The fully cured conductive composite device 600 can display excellent structural stability (e.g., no delamination), which may be facilitated by dynamic transesterification reactions at the interfaces of the previously cured conductive composites 100a, 100b and the newly poured vitrimer that forms the substrate 430, effectively leading to healing behavior. This adhesive-like healing behavior is distinct from that of common epoxy materials, which require a surface preparation procedure of the already cured epoxy surface before adding additional resin. This adhesive-like healing behavior feature of the epoxy vitrimer in the conductive composite device 600 enables the device to have spatial control over electrical conductivity while maintaining uniform mechanical strength throughout the material. This adhesive-like healing behavior feature of the epoxy vitrimer in the conductive composite device 600 also at least partly enables adhesion of different layer and component interfaces within the device such as adhesion of the conductive composites 100a, 100b to the substrate 430 and the conductive element 440.

The conductive composite device 600 was fabricated in one example and then used as a multifunctional, load-bearing electrical conductor as more than 9 kilograms (kg) of weight plates were held while the conductive element 440 in contact with the conductive composites 100a, 100b was turned on. The conductive composite device 600 sample was able to withstand the 9 kg weight successfully with a thickness of only 1.5 mm in this example. This impressive strength further highlights the seamless interfacial bonding between the conductive composites 100a, 100b and the newly poured vitrimer layer that forms the substrate 430 in many examples. Due to fast curing kinetics under mild conditions, each of the conductive composites 100, 100a, 100b, 200 described herein have the potential to be used as on-demand conductive materials that could be deployed in various field applications.

Each of the conductive composites 100, 100a, 100b, 200 described herein also includes and can exhibit thermally triggered shape-memory behavior in many examples. This is due to the combination of their cross-linked structure paired with flexible (e.g., aliphatic linkers) and stiff (e.g., aromatic/cyclohexane moieties) segments. To demonstrate the shape-memory effect, the same conductive composite device 600 sample described above that was used for the weight-hanging demonstration was also wrapped around a cylindrical rod into a coiled shape while being heated above its glass transition temperature in one example. Then, the conductive composite device 600 sample was cooled to room temperature to fix in place or set the coiled shape in this example. To recover its original shape, the coiled shaped conductive composite device 600 sample was heated above its glass transition temperature using a heat gun while the conductive element 440 was on in one example. The original shape of the conductive composite device 600 sample was recovered while the conductive element 440 remained on, indicating that electrical conductivity was preserved during the shape-memory cycle.

The degradability of the conductive composite 100 was investigated in one example by chemical recycling. When the conductive composite 100 reaches end-of-life, valuable resources inside the composite can be retrieved. Because of the presence of ester bonds in the vitrimer matrix 110, the conductive composite 100 can be degraded by base-catalyzed hydrolysis using an aqueous sodium hydroxide (NaOH) solution (e.g., 5 M) in some examples. In these examples, the NaOH solution can simultaneously serve another purpose. For instance, the strongly alkaline solution can also remove gallium oxide shells on the LM elements 150 (e.g., LM microdroplets), which can increase fluidity of the LM elements 150 and aid in reclamation of the LM elements 150.

To demonstrate bulk degradation of the conductive composite device 600 and recovery of components, the same conductive composite device 600 sample that was used for both the weight hanging and shape memory demonstration described above was also submerged in a 100° C. 5 M NaOH solution with a magnetic stir bar stirring at 1000 revolutions per minute (RPM) in one example. The conductive composites 100a, 100b and the conductive composite device 600 sample as a whole mostly retained dimensional stability until day 2, but on day 3 the sample fractured into several pieces with noticeable release of LM droplets in this example. On day 4, the vitrimer matrixes of the conductive composites 100a, 100b were fully disintegrated, and both LM elements and the conductive element 440 were easily extracted from the device using a 200 mesh sieve. As a non-degradable control, a non-ester-containing epoxy (e.g., conventional thermoset) composite was submerged in an identical alkaline solution in this example. However, the control sample did not display any sign of deterioration and retained its structural integrity, indicating that the dynamic ester bond in each of the conductive composites 100a, 100b is relied upon to chemically recycle the composite material in many examples.

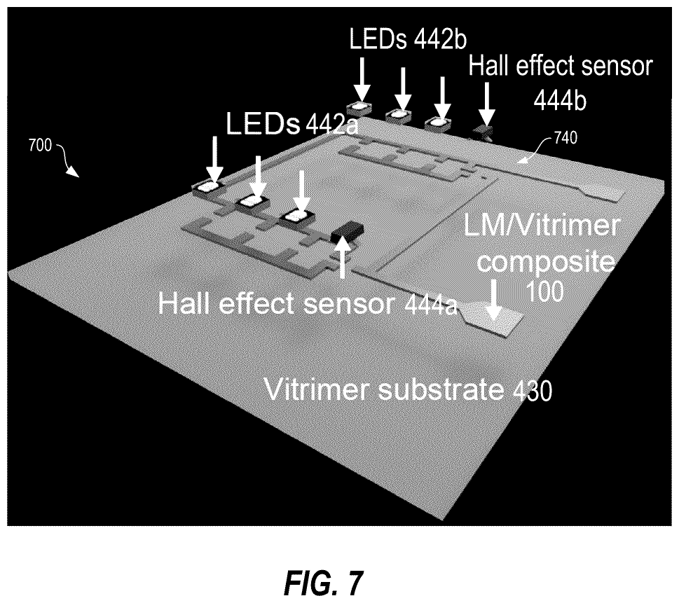

FIG. 7 illustrates a perspective view of another example liquid metal (LM)-vitrimer conductive composite device 700 (or “conductive composite device 700”) according to various aspects and embodiments of the present disclosure. The conductive composite device 700 is another example embodiment of a reclaimable, recyclable, flexible (e.g., bendable, twistable), stretchable (e.g., elastic), and electrically and thermally conductive composite device of the present disclosure.

The conductive composite device 700 is an example alternative embodiment of the conductive composite device 400 described herein with reference to FIGS. 4A and 4B. The conductive composite device 700 can include or more of the same or similar materials, components, structure, attributes, and functional ability as that of the conductive composite device 400.

Referring to FIG. 7, the conductive composite device 700 includes the substrate 430, multiple conductive elements, and multiple traces of the conductive composite 100 coupled (e.g., electrically, mechanically, thermally) to the substrate 430 and the conductive elements. In the example shown, the conductive elements are embodied as and include a first set of LEDs 442a (e.g., three LEDs), a second set of LEDs 442b (e.g., three LEDs), a first Hall effect sensor 444a, and a second Hall effect sensor 444b. The traces of the conductive composite 100, the LEDs 442a, 442b, and the Hall effect sensors 444a, 444b collectively form a parallel circuit or circuit layer 740 (or “circuit 740”) in the conductive composite device 700 shown in this example.

The conductive composite device 700 is an example application of the conductive composite 100 that demonstrates its potential for next generation sustainable electronic devices. The conductive composite device 700 is an example embodiment of a fully vitrimer based circuit board of the present disclosure. For instance, the circuit board is a transparent vitrimer sheet with dynamic ester bonds. The parallel circuit or circuit layer 740 of the conductive composite device 700 in the example shown is embodied as a screen printed LM-vitrimer composite such as the conductive composite 100 that integrates two sets of LEDs 442a, 442b and Hall effect sensors 444a, 444b in parallel in the example shown.

During operation of the conductive composite device 700, the Hall effect sensor 444a, 444b outputs a voltage (Vₒᵤₜ) that changes with magnetic field strength. When there is no magnet, the potential difference between Vₒᵤₜ and V_{cc} is insufficient to turn on the LEDs 442a, 442b in this example. However, as the magnetic field increases, the potential difference between Vₒᵤₜ and V_{cc} increases, eventually powering the LEDs 442a, 442b in this example. As each set of the LEDs 442a, 442b is connected in a parallel circuit configuration in the example shown, both the left and right sides of the conductive composite device 700 can be operated independently. For instance, when a magnet moves from the right side Hall effect sensor 444b to the left side Hall effect sensor 444a, the LEDs 442b at the right side of the conductive composite device 700 dim and eventually shut off and the left side LEDs 442a begin illuminating.

The reconfigurability of the circuit 740 of the conductive composite device 700 illustrated in FIG. 7 and its ability to maintain electrical functionality after being reshaped has also been demonstrated in one example. Heat was applied in this example to reshape the circuit 740, and the circuit 740 continued to function after being reshaped. This demonstration suggests that the vitrimer and LM-vitrimer composite embodiments of the present disclosure such as the conductive composites 100, 200 can be used to create electronics that integrate rigid circuit components, offering potential for future sustainable electronic devices.

The dynamic LM-composite embodiments of the present disclosure provide a pathway towards fully recyclable and mechanically robust electronics, thus advancing the field of green electronic materials. Here, the LM-vitrimer composite embodiments offer several advantages over conventional thermoset-based conductive composite materials that incorporate solid fillers. These features include cohesive structural integrity and mechanical robustness combined with excellent electrical conductivity. Moreover, the high conductivity of the embodiments is not compromised under various operational conditions. Some vitrimer-based circuit board embodiments (e.g., the conductive composite devices 600, 700) can remain fully operational despite significant stress, deformation, and thermally triggered shape-memory transformations, highlighting their potential as an advanced composite material. Some electronic device embodiments (e.g., the conductive composite devices 600, 700) can be chemically recycled via mild hydrolysis leading to recovery of critical components from the vitrimer matrix 110 of the device, including the LM elements 150 and the conductive element 440 (e.g., the LEDs 442a, 442b). The vitrimer matrix 110 can be effectively depolymerized in many examples. In some cases, the byproducts of the depolymerized vitrimer matrix 110 can be re-polymerizable, thereby allowing for recovery of functional vitrimer components that may be used to subsequently re-synthesize pristine materials in a closed-loop process. The structure-property scope of some embodiments can also be greatly expanded in some examples by tuning their material composition using an array of commercially available resin components and hardeners. Unlike existing LM composites, the LM vitrimer material (e.g., the conductive composite 100) of the present disclosure has unique combinations of high modulus, flexibility, and electrical durability while being recyclable. The use of a vitrimer network such as the vitrimer matrix 110 with LM droplets such as the LM elements 150, rather than the permanent covalent networks typical of traditional thermosets or the physical networks found in thermoplastic elastomers, enables the unique combination of electrical conductivity, robust thermomechanical performance, and recyclability described herein, which are key attributes for developing plastic-like, recyclable circuit boards. The embodiments of the present disclosure substantially advance efforts toward creating a sustainable economy for electronic materials.

In one example, the vitrimer matrix 110 can be formed by mixing diglycidyl o-phthalate and 1,3-bis(aminomethyl)cyclohexane (cis- and trans-mixture) in a 1:0.625 ratio using a planetary mixer at 2000 RPM for 4 minutes (min) at 50 Pascals (Pa). The resulting mixture can then be poured into a PDMS mold and cured in a convection oven at approximately 40° C. for 7 hours (h) to obtain a crosslinked sample.

In one example, the conductive composite 100 can be formed by adding LM such as eutectic gallium indium alloy (e.g., Ga/In at a weight ratio of 3:1) into the aforementioned diglycidyl o-phthalate with a calculated ϕ_{LM} to the total volume of the final composite being a value in the range of 0-30 vol %. After hand mixing the LM and diglycidyl o-phthalate mixture for 3 minutes, to change the LM into LM microdroplets, the mixture can be placed in a planetary mixer in this example and mixed at 2000 RPM for 1 min at 50 Pa. Then, 1,3-bis(aminomethyl)cyclohexane (cis- and trans-mixture) can be added to the homogenized mixture in this example. The weight of 1,3-bis(aminomethyl)cyclohexane can be calculated on the basis of the molecular ratio between diglycidyl o-phthalate where the molar ratio between diglycidyl o-phthalate and 1,3-bis(aminomethyl)cyclohexane can be 1:0.625 in this example. Finally, LM and diglycidyl o-phthalate/1,3-bis(aminomethyl)cyclohexane solution can be poured into a PDMS mold and cured in a convection oven at 40° C. for 4 h to obtain a crosslinked film.

The features, structures, or characteristics described above may be combined in one or more embodiments in any suitable manner, and the features discussed in the various embodiments are interchangeable, if possible. In the above description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included. The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims.

The terms “first,” “second,” etc. are used only as labels, rather than a limitation for a number of the objects. It is understood that if multiple components are shown, the components may be referred to as a “first” component, a “second” component, and so forth, to the extent applicable. Further, if a component is described as there being “at least one” of said component, it is understood that this may mean “one or more” of said component. Conversely, if a component is described as there being “one or more” of said component, it is understood that this may mean “at least one” of said component.

As referenced herein in the context of quantity, the terms “a” or “an” are intended to mean “at least one” and are not intended to imply “one and only one.” As referred to herein, the terms “include,” “includes,” and “including” are each intended to be inclusive in a manner similar to the term “comprising.” As referenced herein, the terms “or” and “and/or” are generally intended to be inclusive, that is (i.e.), “A or B” or “A and/or B” are each intended to mean “A or B or both.” As referred to herein, the terms “first,” “second,” “third,” and so on, can be used interchangeably to distinguish one component or entity from another and are not intended to signify location, functionality, or importance of the individual components or entities. As referenced herein, the terms “couple,” “couples,” “coupled,” and/or “coupling” refer to chemical coupling (e.g., chemical bonding), communicative coupling, electrical and/or electromagnetic coupling (e.g., capacitive coupling, inductive coupling, direct and/or connected coupling), mechanical coupling, operative coupling, optical coupling, fluid coupling, thermal coupling, and/or physical coupling.

It should be emphasized that the above-described embodiments of the present disclosure are merely possible examples of implementations set forth for a clear understanding of the principles of the disclosure. Many variations and modifications can be made to the above-described embodiment(s) without departing substantially from the spirit and principles of the disclosure. All such modifications and variations are intended to be included herein within the scope of this disclosure and protected by the following claims.

Therefore, at least the following is claimed:

1. A conductive composite, comprising:
a vitrimer matrix; and
an electrically conductive percolated network of liquid metal elements disposed in the vitrimer matrix.

2. The conductive composite of claim 1, wherein the electrically conductive percolated network of liquid metal elements comprises a plurality of electrically conductive liquid metal elements coupled to one another to collectively form one or more electrical pathways in the vitrimer matrix.

3. The conductive composite of claim 1, wherein the electrically conductive percolated network of liquid metal elements comprises a sintered plurality of electrically conductive liquid metal elements coupled to one another to collectively form one or more electrical pathways in the vitrimer matrix.

4. The conductive composite of claim 1, wherein:
the electrically conductive percolated network of liquid metal elements is disposed in and along a first side of the conductive composite; and
the vitrimer matrix comprises a pure vitrimer layer formed in and along a second side of the conductive composite, the second side of the conductive composite being opposite the first side of the conductive composite.

5. The conductive composite of claim 1, wherein individual ones of the liquid metal elements comprise an alloy of gallium and indium.

6. The conductive composite of claim 1, wherein individual ones of the liquid metal elements comprise a eutectic gallium-indium liquid metal element having a gallium to indium mass ratio of 3:1.

7. The conductive composite of claim 1, wherein the vitrimer matrix comprises 30 percent by volume of the liquid metal elements.

8. The conductive composite of claim 1, wherein at least one of the electrically conductive percolated network of liquid metal elements or the conductive composite has an electrical conductivity of at least 2.0×10⁵ S/m.

9. A conductive composite, comprising:
a vitrimer matrix; and
a liquid metal-vitrimer composite layer disposed in the vitrimer matrix, the liquid metal-vitrimer composite layer comprising an electrically conductive percolated network of liquid metal elements.

10. The conductive composite of claim 9, wherein:
the liquid metal-vitrimer composite layer is disposed in and along a first side of the conductive composite; and
the vitrimer matrix comprises a pure vitrimer layer formed in and along a second side of the conductive composite, the second side of the conductive composite being opposite the first side of the conductive composite.

11. The conductive composite of claim 9, wherein:
the vitrimer matrix comprises 30 percent by volume of the liquid metal elements; and
individual ones of the liquid metal elements comprise an alloy of gallium and indium.

12. A device, comprising:
a substrate; and
a conductive composite coupled to the substrate, the conductive composite comprising:
a vitrimer matrix; and
an electrically conductive percolated network of liquid metal elements disposed in the vitrimer matrix.

13. The device of claim 12, wherein the substrate comprises a vitrimer substrate, a rigid substrate, a flexible substrate, a stretchable substrate, or an elastomeric substrate.

14. The device of claim 12, wherein the conductive composite is at least one of embedded in the substrate or formed on a surface of the substrate.

15. The device of claim 12, wherein the conductive composite is at least one of embedded in the substrate or formed on a surface of the substrate as at least one of an electrode, an electrical trace, an electrical contact pad, or an electrical interconnect.

16. The device of claim 12, wherein the conductive composite is at least one of embedded in the substrate or formed on a surface of the substrate in a defined integrated circuit pattern.

17. The device of claim 12, wherein individual ones of the liquid metal elements comprise at least one of gallium or an alloy of gallium and indium.

18. The device of claim 12, wherein individual ones of the liquid metal elements comprise a eutectic gallium-indium liquid metal element having a gallium to indium mass ratio of 3:1.

19. The device of claim 12, further comprising:
a conductive element positioned in or on the substrate and coupled to the conductive composite.

20. The device of claim 12, further comprising:
at least one of a light emitting diode, an electrode, a passive component, a resistor, a capacitor, an inductor, a sensor, a transformer, or an integrated circuit positioned in or on the substrate and coupled to the conductive composite.
